(19) United States
(12) Patent Application Publication
(10) Pub. No.: US 2005/0136564 A1
(43) Pub. Date: Jun. 23, 2005

(54) Method of laterally growing GaN with indium doping

(76) Inventors: Jeong Tak Oh, Suwon (KR); Je Won Kim, Seoul (KR)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/839,568

(22) Filed: May 6, 2004

(30) Foreign Application Priority Data
Dec. 19, 2003 (KR) 2003-93654

(51) Int. Cl. H01L 21/00; C30B 23/00; C30B 25/00; C30B 28/12; C30B 28/14

(52) U.S. Cl. 438/29

(57) ABSTRACT

Disclosed herein is a method of laterally growing GaN with In doping, which enables formation of a GaN layer in a shorter period of time by increasing a lateral growth rate of GaN with the In doping when laterally growing GaN with the LEO method. The method comprises the steps of preparing a substrate for growing GaN, growing a GaN epitaxial layer on the substrate, forming a mask on the GaN epitaxial layer so that a predetermined portion of the GaN epitaxial layer is exposed, and overgrowing GaN to a predetermined thickness by doping a predetermined amount of In. When laterally growing the GaN layers with the LEO method, a lateral growth rate of GaN can be increased by the In doping, so that the manufacturing time can be shortened and the productivity can be enhanced.

### BACKGROUND OF THE INVENTION

1. Field of the Invention

The present invention relates to a method of laterally growing a nitride semiconductor material, and more particularly to a method of laterally growing gallium nitride (GaN) with In doping, which enables formation of a GaN layer in a shorter period of time by increasing a lateral growth rate of GaN with the In doping when laterally growing GaN with the LEO (Lateral Epitaxy Overgrowth) method, and which enables growth of a high quality GaN having a low dislocation density by forming a broader dielectric mask with the increase of lateral growth rate.

2. Description of the Related Art

Recently, a nitride semiconductor using nitride, such as GaN, has been in the spotlight as a necessary material for a photoelectronic material or an electronic device, based on its excellent physical and chemical characteristics. In particular, as a nitride semiconductor LED can generate light having wavelengths of green, blue and UV light and a brightness thereof is rapidly enhanced with a technological development, it has many applications in several fields, such as a full color video display board, an illuminating apparatus, etc.

Such nitride semiconductors use a nitride semiconductor material with the formula AlₓIn_{y}Ga_{(1-x-y)}N (where 0≦x≦1, 0≦y≦1, 0≦x+y≦1). In this regard, investigations have been actively undertaken particularly on the semiconductor LED with GaN. Meanwhile, although there is no commercially available substrate which has an identical crystal structure to that of the nitride semiconductor material, such as GaN, and which is in lattice matching with the material, a sapphire substrate is generally used as a dielectric substrate in the nitride semiconductor LED.

In general, a single crystal thin film comprising the nitride semiconductor material is grown on the sapphire substrate, whose structure is different from that of the single crystal thin film, using a heteroepitaxy method, such as the MOCVD (Metal Organic Chemical Vapor Deposition) process, the MBE (Molecular Beam Epitaxy) process, etc. In this case, defects, which are referred to as “dislocations,” are created due to the differences in lattice parameters and in thermal expansion coefficients between the sapphire substrate and the thin film of the nitride semiconductor material.

In order to decrease dislocation densities, there have been suggested as a technology for decreasing the dislocations the LEO (Lateral Epitaxy Overgrowth) method [also referred to as the ELOG (Epitaxial Lateral Overgrowth) method] of laterally growing GaN, a method of forming a low temperature interlayer, a Si/N processing method, etc.

In particular, the LEO method is known to be a technology capable of ensuring formation of a high quality epitaxial layer with low dislocation density. By the LEO method, the defects created at the interface between the sapphire substrate and the GaN layer are prevented from moving to the upper layer by the lateral growth of GaN. By the LEO method, a dielectric mask is formed on the sapphire substrate or on the GaN epitaxial layer primarily grown on the sapphire substrate and GaN is overgrown on a portion at which the mask is not formed, so that GaN is laterally grown on the mask.

FIGS. 1a to 1d show a method of growing the GaN layer according to the above conventional LEO method. By the LEO method, as shown in FIG. 1a, at first, a GaN epitaxial layer 11 is primarily grown on a sapphire substrate 10. As shown in FIG. 1b, on the GaN epitaxial layer 11 primarily grown, a mask 12 with a prescribed pattern is formed using a silicone oxide film or a silicone nitride film. Subsequently, as shown in FIG. 1c, the GaN layer is overgrown on the portion where the mask 12 is not formed. That is, on the mask 12, a GaN layer 13 is grown in the lateral direction as indicated by an arrow in FIG. 1c. As the lateral growth of the GaN layers 13 finishes, the growth of the GaN layer 13 is completed, as shown in FIG. 1d.

It is generally known that in case of using the LEO method, the dislocations moving in the GaN layers are reduced. As shown in FIG. 2, in the portion where the epitaxial layer 11 primarily grown is exposed, the underlying dislocations A move to the GaN layer 13 overgrown after the primary growth, while in the portion covered with the mask 12, no underlying dislocations move to the GaN layer on the mask 12 due to the lateral overgrowth of the GaN layer, thereby reducing the defects.

However, in case of growing the GaN layer with such a method, there are problems in that the dislocations A in the portion which the mask does not cover move upward without any obstruction, and that a high density of the dislocations B appear at the interfaces where the laterally overgrowing GaN layers 13 meet each other. In this regard, the density of the dislocations can be reduced by decreasing the number of dielectric masks 12 and by providing a broader mask. However, since the lateral growth rate of GaN is very low to the extent of 3.45 μm per hour, it is not possible for the method of forming the broader mask to be practically applied in the industry.

Thus, in order to prevent the defects, such as dislocations caused by lattice mismatching between the sapphire substrate and the nitride semiconductor material such as GaN, there is a need in the art to provide a new method of laterally growing GaN, which can increase a lateral growth rate of GaN so as to allow formation of a broader dielectric mask when using the LEO method.

### SUMMARY OF THE INVENTION

Therefore, the present invention has been made in view of the above problems, and it is an object of the present invention to provide a method of laterally growing GaN with In doping, which can increase a lateral growth rate of GaN by doping a predetermined amount of In when laterally growing GaN using the LEO method.

In accordance with an aspect of the present invention, the above and other objects can be accomplished by the provision of a method of laterally growing GaN with In doping, the method comprising the steps of:
a) preparing a substrate for growing GaN;
b) forming a GaN epitaxial layer on the substrate;
c) forming a mask on the GaN epitaxial layer such that a predetermined portion of the GaN epitaxial layer is exposed; and
d) overgrowing GaN to a predetermined thickness on the GaN epitaxial layer and on the mask by doping a predetermined amount of In.

In the method of laterally growing GaN with the In doping, indium may be doped in an amount of 0 to 10%. Further, the step d) may comprise the step of adjusting an overgrowth rate of GaN by changing an amount of In to be doped.

### BRIEF DESCRIPTION OF THE DRAWINGS

A method of laterally growing GaN with In doping in accordance with the present invention will be more clearly understood from the following detailed description taken in conjunction with the accompanying drawings, in which:

FIGS. 1a to 1d are sectional views of a flow diagram showing a conventional method of laterally growing GaN;

FIG. 2 is a sectional view illustrating dislocations in the GaN layers grown by the conventional method;

FIG. 3 is a sectional view of a sample for an experiment on the lateral growth of GaN according to the present invention;

FIGS. 4a and 4b are photographs showing the laterally grown GaN which is not doped with In and the laterally grown GaN doped with indium according to the present invention, respectively;

FIG. 5 is a graph showing relationship between an input rate of In and a lateral growth rate of GaN according to the present invention; and

FIG. 6 is a graph showing the result of X-ray diffraction analysis for a tilt caused by the indium doping according to the present invention.

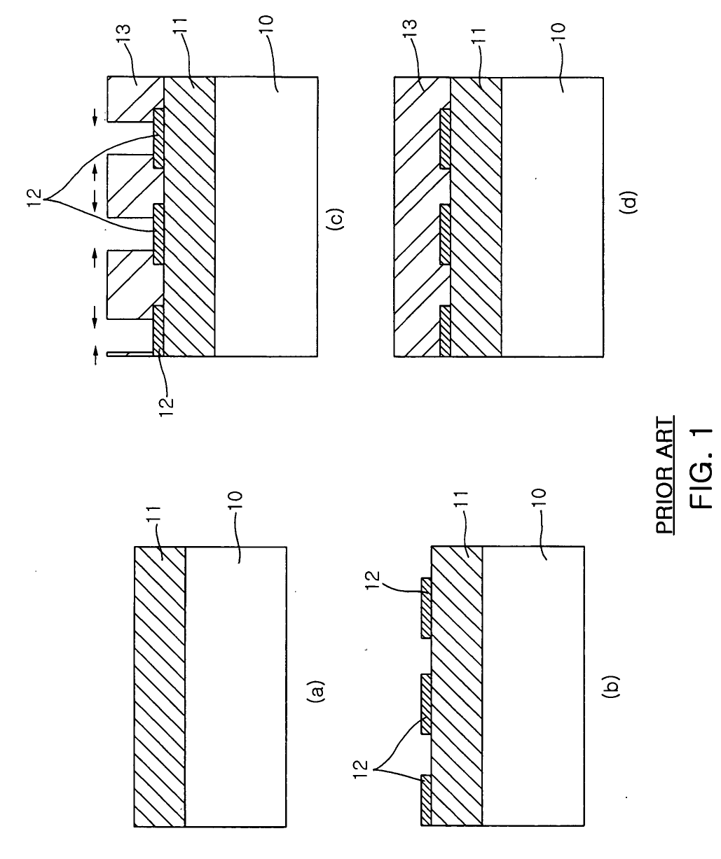

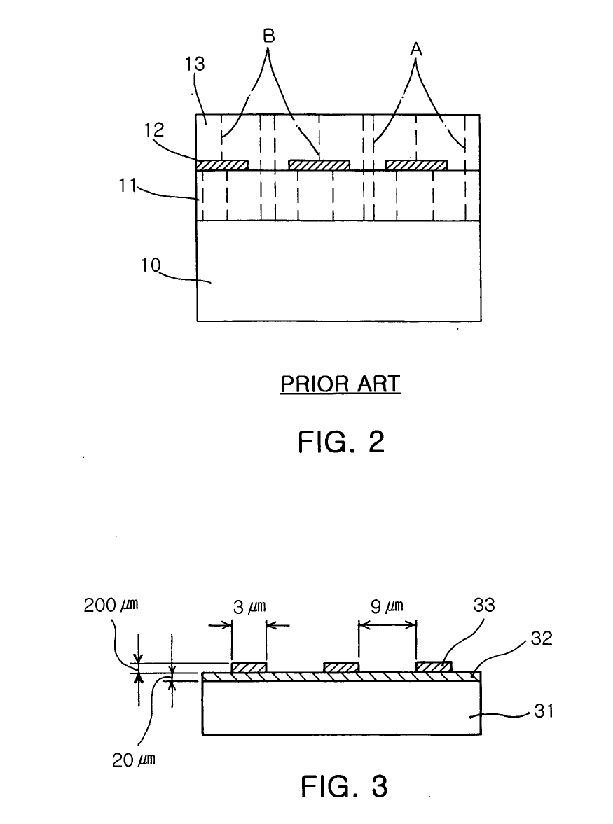

### DESCRIPTION OF THE PREFERRED EMBODIMENTS

Now, a preferred embodiment of the present invention will be described in detail with reference to the accompanying drawings.

In accordance with the embodiment of the present invention, a method of laterally growing GaN with In doping is provided as follows.

As shown in FIG. 3, at first, after a substrate 31 for growing GaN is prepared, a GaN epitaxial layer 32 is formed on the substrate. Then, a mask 33 is formed on the GaN epitaxial layer 32 such that a predetermined portion of the GaN epitaxial layer 32 is exposed. Finally, GaN (not shown) is overgrown to a predetermined thickness on the GaN epitaxial layer 32 and on the mask 33 by doping a predetermined amount of In.

Preferably, In is doped in an amount of 0 to 10%. The overgrowth rate of GaN may be adjusted by changing an amount of In to be doped.

The inventors performed the following experiment to observe the relation between an increase of lateral growth rate of GaN and the amount of In doped.

As shown in FIG. 3, after growing a GaN epitaxial layer 32 to a thickness of 2 μm as a seed layer on a sapphire layer 31, a SiO₂ mask 33 having predetermined patterns with a thickness of 200 μm was formed on the GaN epitaxial layer 32.

The mask 33 was formed on the GaN epitaxial layer 32 to have a parallel band shape by the following steps. At first, a SiO₂ mask was deposited on the GaN epitaxial layer 32 to have a thickness of 200 nm using SiH₄ and N₂O sources by the PECVD (Plasma Enhanced Chemical Vapor Deposition) process. Then, parallel band shape patterns were transferred onto the mask by the UV photolithography process and the rest of the mask not patterned with the shapes was removed by dry etching, thereby forming the mask 33 having the predetermined parallel band shape patterns. Through the above steps, the mask 33 of the parallel band shape was formed in the <1-100> directions, in which the patterns of the mask 33 were formed to have a width of 3 μm, respectively, and have a space of 9 μm between the patterns. Although the band shape patterns were transferred on the mask in the experiment, it should not be considered that the present invention is limited to the shape.

Subsequently, GaN was overgrown using the MOCVD process. As sources of Ga and N, Trimethylgallium (TMGa) and ammonia (NH₃) were supplied at a rate of 215 μmole per minute and 7,000 sccm per minute (where a ratio of V/III is 1,451), respectively, while H₂ is used as a carrier gas. In such a process of growing GaN, with the amount of Trimethylinlium (TMIn) doped as a source of In varied from 20 μmole per minute to 40 μmole per minute, a growth rate of GaN was observed. Temperature and reaction pressure were 1,190° C. and 150 mbar, respectively.

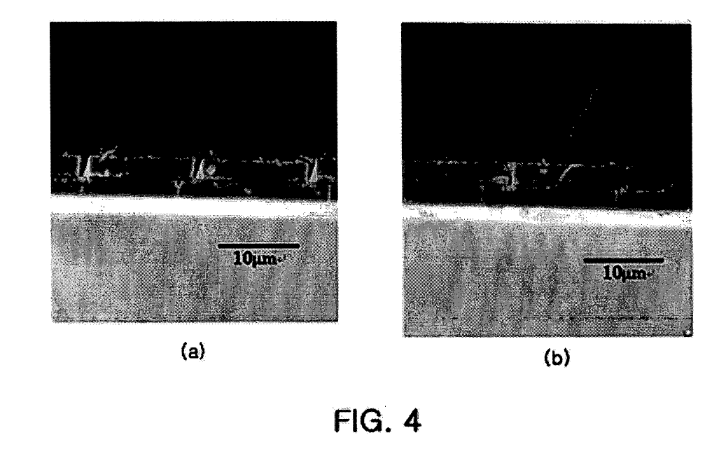

FIGS. 4a and 4b is a photograph showing the laterally grown GaN in which indium is not doped, and a photograph showing the laterally grown GaN in which indium is doped, in the same period of time, respectively. Both FIGS. 4a and 4b were photographed using SEM (Scanning Electron Microscopy). As is apparent from FIGS. 4a and 4b, in the lateral growth of GaN for the same period of time, the growth rate of GaN in which In is doped is higher than that of GaN in which In is not doped.

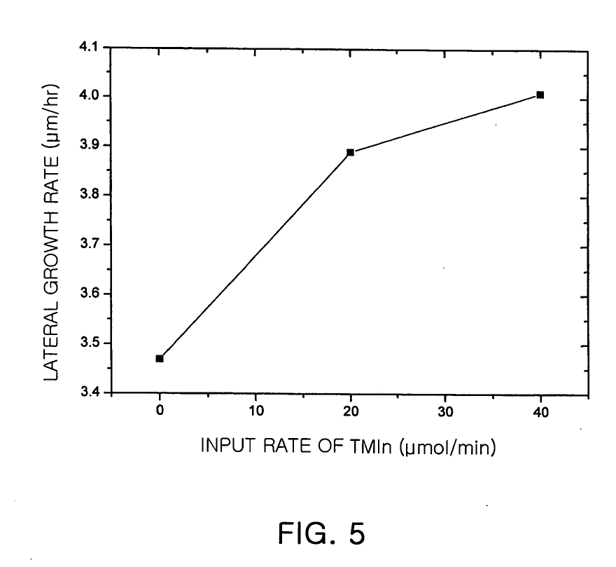

FIG. 5 is a graph plotting relationship between an input rate of In and a lateral growth rate of GaN according to the experiment. As is shown in FIG. 5, if TMIn is inputted in a rate of 20 μmole per minute during the MOCVD process, the lateral growth rate of GaN is about 3.88 μm per hour, while if TMIn is inputted in a rate of 40 μmole per minute, the lateral growth rate of GaN was about 4.01 μm per hour. As the rate of TMIn inputted increases, the lateral growth rate of GaN increases almost linearly. Meanwhile, if TMIn is not inputted, the lateral growth rate of the GaN layers is 3.47 μm per hour. As a result, it can be seen that even though the later growth rate of GaN increases due to the inputted TMIn, the increased rate thereof will gradually decrease as the rate of TMIn inputted increases.

As such, if In is doped when using the LEO method, the lateral growth rate of GaN increases, as In atoms participate in bonding of N and Ga causing a free diffusion of Ga atoms on the surface of GaN which is laterally growing, whereby the In atoms act as a surfactant activating a surface diffusion of Ga atoms. As the amount of In doped increases, the lateral growth rate also increases, while the increase rate thereof gradually decreases. Thus, a suitable amount of In to be doped is preferably in a range of 0 to 10%. Specifically, if the amount of In doped is more than 10%, a different material layer with a composition of InGaN can be formed, instead of forming the GaN doped with In. Thus, preferably, the maximum amount of In doped in the growth of GaN layers is to be 10%.

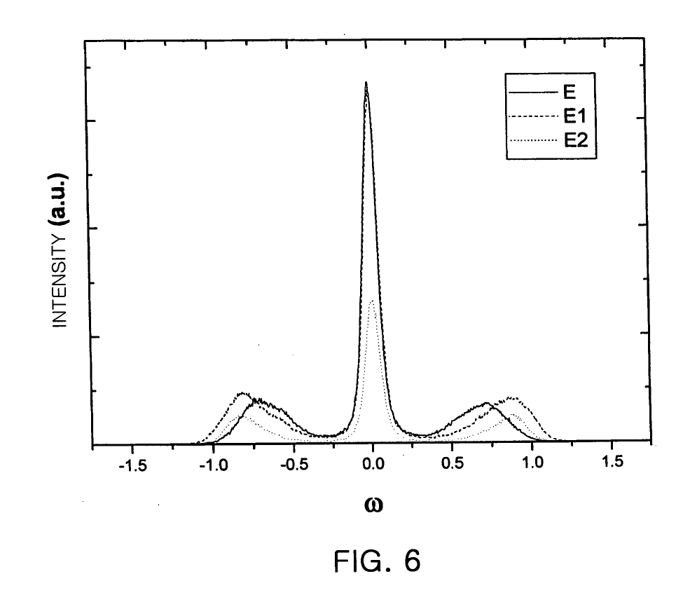

FIG. 6 is a graph plotting the result of an X-ray diffraction analysis for a tilt caused by the In doping according to the experiment. Such as in the experiment, in case of laterally growing GaN with the dielectric mask with the predetermined band shape patterns formed in the <1-100> directions using the MOCVD process, the dielectric mask with the predetermined band shape patterns becomes bent in a direction perpendicular to a direction in which the mask is formed, what is referred to as tilt. Although the exact reason behind the tilt has yet been determined, it is generally known that the thermal stress, the materials used for the dielectric mask during the lateral growth, etc. cause the tilt. Particularly, reports say that the tilt increases as the lateral growth rate increases.

As shown in FIG. 6, in case of the lateral growth of GaN in which In is not doped, the tilt E1 (the peak value on both sides centered on ω=0) is about 0.715°, while in case of inputting TMIn in a rate of 20 μmole per minute, the tilt E2 is about 0.86°. These results indicate that the lateral growth rate of the GaN layers increases as a higher amount of In is doped.

As apparent from the above description, the present invention enables the lateral growth rate to be increased with the In doping in the lateral growth of GaN using the LEO method, and enables the lateral growth rate of GaN to be adjusted, as needed, by adjusting an amount of In to be doped.

According to the present invention, there are provided advantageous effects that the lateral growth rate of GaN is increased with the In doping in the lateral growth of GaN using the LEO method, thereby reducing the manufacturing times and enhancing the productivity thereof. Specifically, as the lateral growth rate of GaN is increased with the In doping when using the LEO method, a broader dielectric mask can be provided, so that the density of dislocations can be reduced when laterally growing the GaN thin film thereby forming a GaN layer with an excellent crystal. Further, the device manufactured by the method of the present invention can exhibit excellent electrical and optical properties.

Although the preferred embodiments of the present invention have been disclosed for illustrative purpose, those skilled in the art will appreciate that various modifications, additions and substitutions are possible without departing from the scope and spirit of the invention as disclosed in the accompanying claims.

1. A method of laterally growing GaN with In doping, the method comprising the steps of:
a) preparing a substrate for growing GaN;
b) growing a GaN epitaxial layer on the substrate;
c) forming a mask on the GaN epitaxial layer such that a predetermined portion of the GaN epitaxial layer is exposed; and
d) overgrowing GaN by doping a predetermined amount of In on the GaN epitaxial layer and on the mask to a predetermined thickness.

2. The method as set forth in claim 1, wherein indium is doped in an amount of 0 to 10%.

3. The method as set forth in claim 1, wherein the step d) comprises the step of adjusting an overgrowth rate of GaN by changing an amount of indium to be doped.
